(19) United States
(12) Patent Application Publication
(10) Pub. No.: US 2006/0138486 A1
(43) Pub. Date: Jun. 29, 2006

(54) CMOS image sensor and method for fabricating the same

(76) Inventor: Keun Hyuk Lim, Eumseong-gun (KR)

Correspondence Address: MCKENNA LONG & ALDRIDGE LLP;Song K. Jung, 1900 K Street, N.W., Washington, DC, 20006, US

(21) Appl. No.: 11/315,149

(22) Filed: Dec. 23, 2005

(30) Foreign Application Priority Data
Dec. 23, 2004 (KR) 2004-0111470

(51) Int. Cl. H01L 31/113

(52) U.S. Cl. 257/292

(57) ABSTRACT

A CMOS image sensor and a method for fabricating the same forms a trench-shaped transfer gate that serves to better transfer electrons generated by light incident on photodiodes, thus obtaining improved transfer characteristics. The CMOS image sensor includes a semiconductor substrate having at least one active region defined by a shallow trench isolation region; a light-receiving region formed in a surface of the semiconductor substrate; and a transfer gate buried in the semiconductor substrate between the light-receiving region and the at least one active region, wherein the transfer gate has a trench shape of a predetermined depth.

This application claims the benefit of Korean Patent Application No. 10-2004-0111470, filed on Dec. 23, 2004, which is hereby incorporated by reference for all purposes as if fully set forth herein.

### BACKGROUND OF THE INVENTION

1. Field of the Invention

The present invention relates to complementary metal-oxide-semiconductor (CMOS) image sensors and more particularly, to a CMOS image sensor and a method for fabricating the same, which employs a trench-shaped transfer gate that facilitates the transfer of electrons generated by light incident on a photodiode.

2. Discussion of the Related Art

An image sensor is a semiconductor device for converting optical images to electrical signals and may be categorized as a CMOS image sensor or a charge-coupled device. A charge-coupled device includes a plurality of metal-oxide-silicon (MOS) capacitors arranged in proximity to one another, wherein charge carriers are stored in and transferred to the capacitors. A CMOS image sensor, on the other hand, applies CMOS technology and thus employs a control circuit and a signal processing circuit as peripheral circuitry that includes a switching mode that sequentially detects outputs of unit pixels using a multitude of MOS transistors corresponding to the number of the unit pixels. The unit pixels are arrayed on a semiconductor or silicon substrate.

The CMOS image sensor includes a photo-sensing area, e.g., a photodiode, for sensing light and a logic circuit area for processing the sensed light as an electric signal. Light incident on the photodiode generates electron-hole pairs, wherein holes are absorbed into the semiconductor substrate and the electrons accumulate in the photodiode. The accumulated electrons selectively turn on one of the above-mentioned MOS transistors, under the control of a gate formed of a conductive material layer. The gate is conventionally patterned to be disposed adjacent the photodiode on the surface of the semiconductor substrate. The photodiode is formed in the semiconductor substrate by an ion-implantation process using a mask formed over the gate structure.

The gate, however, is usually partially exposed because of inherent inaccuracies in a photo-masking process of the ion implantation process. This causes ions to also become implanted in the silicon substrate through the exposed portion of the gate. Thus, a channel region formed below the gate may be affected by the implanted ions. This results in a variation in transistor characteristics across the array and yield is lowered accordingly.

### SUMMARY OF THE INVENTION

Accordingly, the present invention is directed to a CMOS image sensor and a method for fabricating the same that substantially obviates one or more problems due to limitations and disadvantages of the related art.

An advantage of the present invention is to provide a CMOS image sensor and a method for fabricating the same which facilitates electron mobility.

Another advantage of the present invention is to provide a CMOS image sensor and a method for fabricating the same which obtains improved transfer characteristics.

Another advantage of the present invention is to provide a CMOS image sensor and a method for fabricating the same which prevents an ion-plantation process for forming a photodiode from adversely affecting a channel region.

Another advantage of the present invention is to provide a CMOS image sensor and a method for fabricating the same which enhances transistor uniformity across a pixel array and promotes higher yields.

Additional features and advantages of the invention will be set forth in the description which follows, and in part will be apparent from the description, or may be learned by practice of the invention. The objectives and other advantages of the invention will be realized and attained by the structure and method particularly pointed out in the written description and claims hereof as well as the appended drawings.

To achieve these and other advantages and in accordance with the purpose of the present invention, as embodied and broadly described, there is provided a CMOS image sensor comprising a semiconductor substrate having at least one active region defined by a shallow trench isolation region; a light-receiving region formed in a surface of the semiconductor substrate; and a transfer gate in the semiconductor substrate between the light-receiving region and the at least one active region, wherein the transfer gate has a trench shape of a predetermined depth.

In another aspect of the present invention, there is provided a method for fabricating a CMOS image sensor. The method comprises forming a trench in a semiconductor substrate; filling the trench with polysilicon; forming a transfer gate by patterning the polysilicon to remain in the trench; forming, using a photo-masking process, a lightly doped region as a photodiode on one side of the transfer gate by implanting N⁻-type ions into the semiconductor substrate; implanting P⁻-type ions in a surface region of the photodiode; and forming an active region as a heavily doped region by implanting N⁺-type ions into the semiconductor substrate on the other side of the transfer gate.

In another aspect of the present invention, there is provided a method for fabricating a CMOS image sensor. The method comprises defining at least one active region by a shallow trench isolation region in a semiconductor substrate; forming a light-receiving region in a surface of the semiconductor substrate; and forming a transfer gate in the semiconductor substrate between the light-receiving region and the at least one active region, wherein said transfer gate has a trench shape of a predetermined depth.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIG. 1 is a sectional view of a CMOS image sensor according to the present invention; and

FIG. 2 to FIG. 7 are sectional views illustrating a method for fabricating a CMOS image sensor according to the present invention.

### DETAILED DESCRIPTION OF THE INVENTION

Reference will now be made in detail to embodiments of the present invention, examples of which are illustrated in the accompanying drawings. Wherever possible, like reference designations will be used throughout the drawings to refer to the same or similar parts.

The CMOS image sensor is structured as an array of pixels, wherein each pixel is comprised of an arrangement of four transistors and a photodiode.

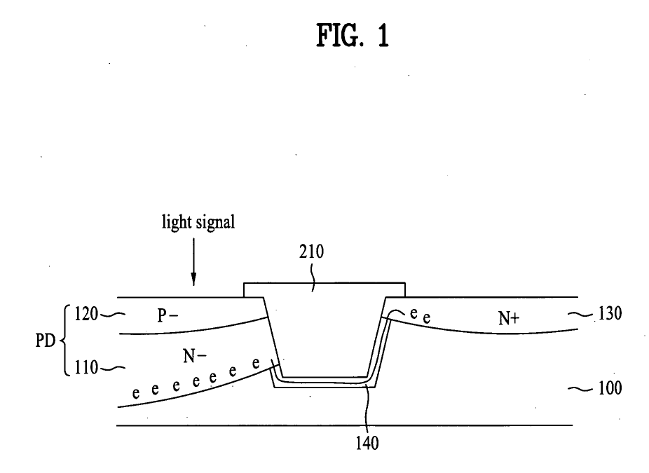

As shown in FIG. 1, a semiconductor or substrate or silicon substrate 100 of the CMOS image sensor according to the present invention includes a photodiode PD serving as a light-receiving region formed in a predetermined surface of the semiconductor substrate. An active region 130, which is preferably formed of polysilicon, is buried in the semiconductor substrate 100 in a trench shape. Thus, if a transfer gate 210 is turned on, a channel region 140 is formed deep inside the semiconductor substrate 100 to extend, below a trench, from the photodiode PD to the active region 130. Therefore, with transfer gate 210 turned on, accumulated electrons (e) generated according to an optical or light signal incident on the photodiode PD move, with virtually no loss, along the channel region 140 from the photodiode PD to the active region 130. Here, the photodiode PD is made up of a P⁻-type region 120 at the surface and an N⁻-type region 110 formed below the surface, i.e., adjacent the channel region 140. The active region 130 is an N⁺ region spaced apart from the photodiode PD by a predetermined interval.

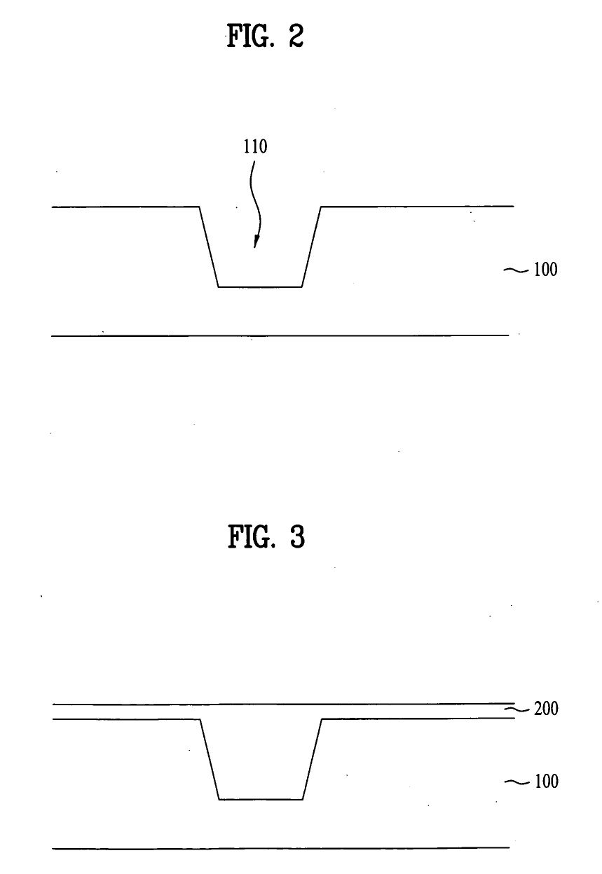

FIGS. 2-7 illustrate a method for fabricating a CMOS image sensor according to an exemplary embodiment of the present invention.

Referring to FIG. 2, a nitride film (not shown) is formed and patterned on the semiconductor substrate 100. A trench 110 is formed in the silicon of the semiconductor substrate 100 by etching the semiconductor substrate using the nitride film pattern as a mask. The etching of the trench 110 will be performed to reach a predetermined depth to thereby establish a thickness of the transfer gate 210 at least equal to the depth of a shallow trench isolation region (not shown). The thickness may be 3000 Å or more.

Referring to FIG. 3, a layer of polysilicon 200 is deposited on the semiconductor substrate 100 to fill the trench 110 and cover the shallow trench isolation region selectively formed by a field oxide film. The shallow trench isolation region serves to divide semiconductor substrate 100 into a plurality of active regions, thereby defining each active region 130.

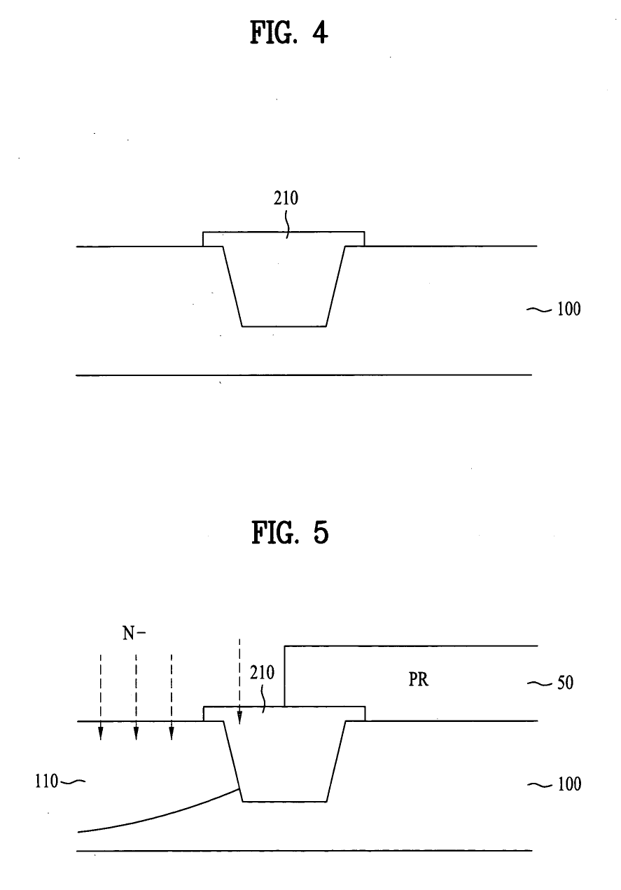

Referring to FIG. 4, the transfer gate 210, filling the trench 110, is formed by patterning the polysilicon 200. The patterned polysilicon layer thus remains in and around the region of the trench 110. Since the transfer gate 210, which serves to move electrons generated by the photodiode PD, is formed in a trench shape of a substantial depth, electron mobility can be facilitated regardless of minor inaccuracies in a subsequent photo-masking process to form the photodiode PD. Thus, improved transfer characteristics are obtained.

Referring to FIG. 5, a photoresist (PR) film is deposited on the structure obtained as above and patterned to form a photoresist pattern 50 covering a portion or one side of the transfer gate 210. The other side and adjacent areas of the semiconductor substrate 100 are therefore exposed. The photoresist pattern 50 intends to shield the transfer gate 210 after a photo-masking process to form the photodiode PD. Thus, using the photoresist pattern 50 as a mask, N⁻-type ions are implanted into the exposed areas of the semiconductor substrate 100 to form a lightly doped region 110.

Accordingly, even if photo-masking inaccuracies occur such that the transfer gate 210 is partially exposed during ion implantation, no ion implantation occurs in the channel region 140 below the transfer gate since the transfer gate has a trench shape buried in the substrate. Furthermore, no ion implantation occurs due to the substantial depth of the trench 110 for forming the transfer gate 210, which is thickly formed to have a depth of at least 3000 Å. Therefore, there can be no damage or adverse effects to the channel region 140 even if the transfer gate 210 is partially exposed due to an inaccurate formation of the photoresist pattern 50.

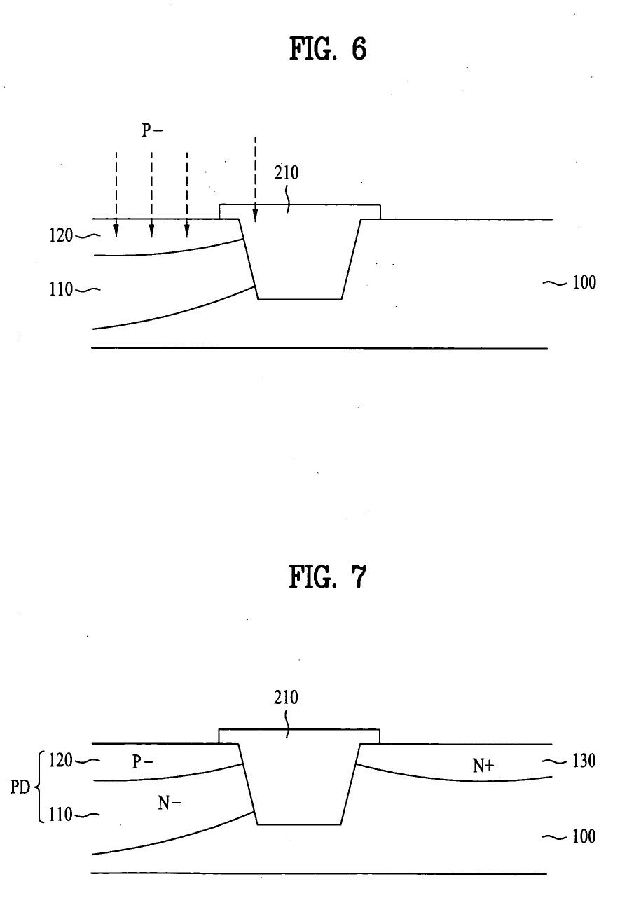

Referring to FIG. 6, using the photoresist pattern 50 as a mask, P⁻-type ions are implanted into the exposed areas of the semiconductor substrate 100 to form the P⁻-type region 120 toward the surface above the N⁻-type region 110. Thus, the photodiode PD, which includes the P⁻-type and N⁻-type regions 120 and 10, is completed.

Referring to FIG. 7, after removing the photoresist pattern 50, another mask is used to form the active region 130 on the other side of the transfer gate 210, i.e., on the other side of the trench 110. The active region 130 serves as source or drain. In doing so, N⁺-type ions are implanted into unmasked areas of the semiconductor substrate 100 to form a heavily doped region.

By adopting the CMOS image sensor and the method for fabricating the same according to the present invention, improved transfer characteristics are enabled since the transfer gate that serves to move electrons generated by light incident on the photodiodes is formed in a trench shape. In addition, due to the trench-shaped transfer gate, the channel region of the transfer gate is formed at a substantial depth inside the semiconductor substrate, so that leakage current, which may be caused by surface charge and surface damage, can be reduced. Furthermore, since the lightly doped ion implantation layer of the photodiodes is spaced apart from the channel region, it is possible to remove parasitic capacitance of a depletion region between the lightly doped ion implantation layer and the channel region. Thus, the speed of the transistor is improved.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A CMOS image sensor comprising:
a semiconductor substrate having at least one active region defined by a shallow trench isolation region;
a light-receiving region formed in a surface of said semiconductor substrate; and
a trench shaped transfer gate in said semiconductor substrate between said light-receiving region and the at least one active region.

2. The CMOS image sensor of claim 1, wherein the transfer gate is formed of polysilicon.

3. The CMOS image sensor of claim 1, wherein said light-receiving region is a photodiode.

4. The CMOS image sensor of claim 1, wherein the transfer gate has a predetermined depth that is at least equal to a depth of the shallow trench isolation region.

5. The CMOS image sensor of claim 1, wherein the transfer gate has a predetermined depth of not less than 3000 Å.

6. The CMOS image sensor of claim 1, wherein said light-receiving region is disposed at a predetermined interval from the at least one active region.

7. The CMOS image sensor of claim 1, wherein said active region 130 is an N⁺ region and said light-receiving region is a photodiode made up of a P⁻-type region at the surface of said semiconductor substrate and an N⁻-type region formed below the P⁻-type region and wherein the N⁻-type region is adjacent a channel region extending from the photodiode to the at least one active region.

8. A method for fabricating a CMOS image sensor comprising:
forming a trench in a semiconductor substrate;
filling the trench with polysilicon;
forming a transfer gate by patterning the polysilicon to remain in the trench;
forming, using a photo-masking process, a lightly doped region as a photodiode on one side of the transfer gate by implanting N⁻-type ions into the semiconductor substrate;
implanting P⁻-type ions in a surface region of the photodiode; and
forming an active region as a heavily doped region by implanting N⁺-type ions into the semiconductor substrate on the other side of the transfer gate.

9. The method of claim 8, wherein the photo-masking process comprises:
forming a photoresist pattern by depositing a photoresist film on the semiconductor substrate including the patterned polysilicon; and
patterning the photoresist film according to the forming of the transfer gate and the active region.

10. The method of claim 9, wherein forming said lightly doped region is performed using the photoresist pattern as a mask.

11. A method for fabricating a CMOS image sensor, comprising:
defining at least one active region by a shallow trench isolation region in a semiconductor substrate;
forming a light-receiving region in a surface of the semiconductor substrate; and
forming a transfer gate in the semiconductor substrate between the light-receiving region and the at least one active region, wherein said transfer gate has a trench shape of a predetermined depth.

12. The method of claim 11, wherein said trench shape establishes a predetermined thickness of the transfer gate.

13. The method of claim 12, wherein the predetermined thickness is at least equal to the depth of the shallow trench isolation region.

14. The method of claim 12, wherein the predetermined thickness is not less than 3000 Å.
